(19) United States
(12) Patent Application Publication
(10) Pub. No.: US 2013/0241371 A1
(43) Pub. Date: Sep. 19, 2013

(54) FASTENING STRUCTURE AND ELECTRONIC DEVICE

(71) Applicant: JI-FENG QIU, Shenzhen City (CN)

(72) Inventor: JI-FENG QIU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/535,531

(22) Filed: Jun. 28, 2012

(30) Foreign Application Priority Data
Mar. 13, 2012 (CN) 201210064264.4

(51) Int. Cl. F16B 37/04; H05K 5/02

(52) U.S. Cl. 312/223.1; 411/103

(57) ABSTRACT

A fastening structure for fastening an assembly member to a housing, includes a mounting member, and a nut. The mounting member protrudes from the housing. The mounting member defines a receiving groove, and a mounting hole communicating with receiving groove. The nut is received in the receiving groove, the nut is capable of engaging with a screw inserted through the assembly member and the mounting hole to fasten the assembly member to the housing.

### BACKGROUND

1. Technical Field

The present disclosure relates to fastening structures, and particularly to a fastening structuring for fastening a nut, and an electronic device using the fastening structure.

2. Description of Related Art

A screw and a nut cooperatively forming a fastening structure to fasten an assembly member is widely used. For example, when an assembly member is fasten to an electronic device with a plastic housing by the above fastening structure, the nut is commonly secured to a plastic post of the housing by hot melting. However, the hot melting method is costly. Further, when the hot melting temperature is not high enough to make the post melt, the post is not properly formed and the nut is difficult to be secured to the housing.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an isometric view of an electronic device.

FIG. 2 is an exploded view of an electronic device in FIG. 1.

FIG. 3 is a view of a nut being assembled to the electronic device in FIG. 1.

FIG. 4 is a view of a nut having been assembled to the electronic device in FIG. 1.

### DETAILED DESCRIPTION

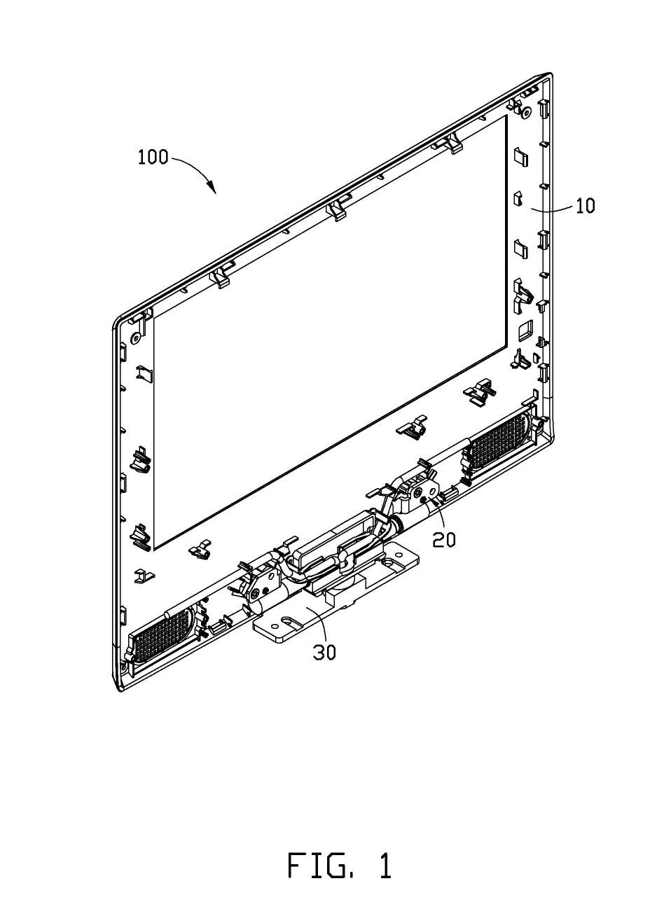

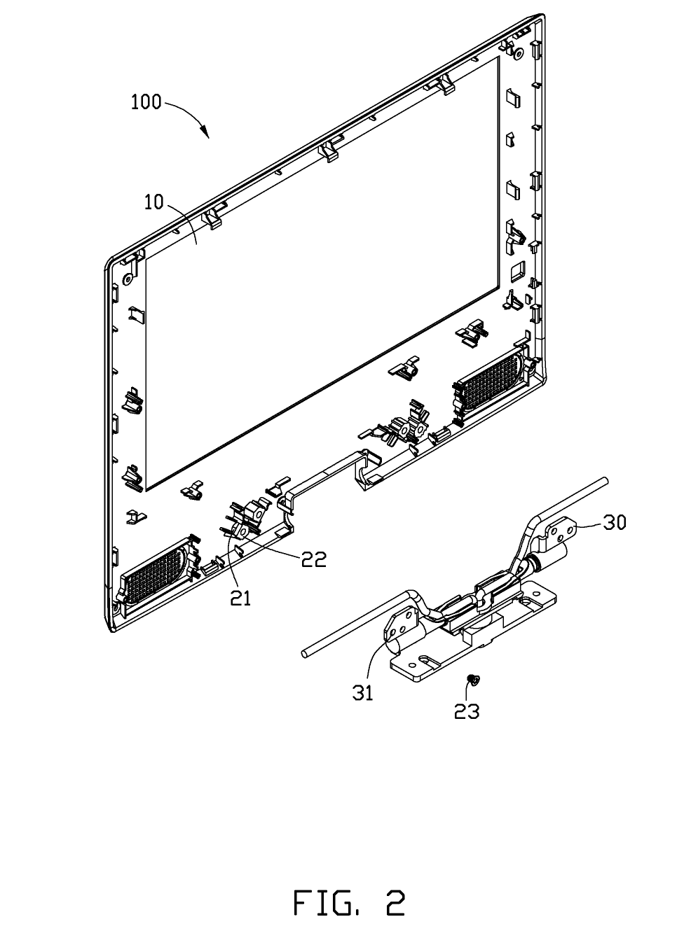

Referring to FIGS. 1 and 2, an electronic device 100 includes a housing 10, an assembly member 30, and two fastening structures 20 for securing the assembly member 30 to the housing 10. The assembly member 30 defines two through holes 31 according to the fastening structures 20. In another embodiment, the electronic device 100 includes a plurality of fastening structures 20, and the assembly member 30 defines a plurality of through holes 31 according to the fastening structures 20.

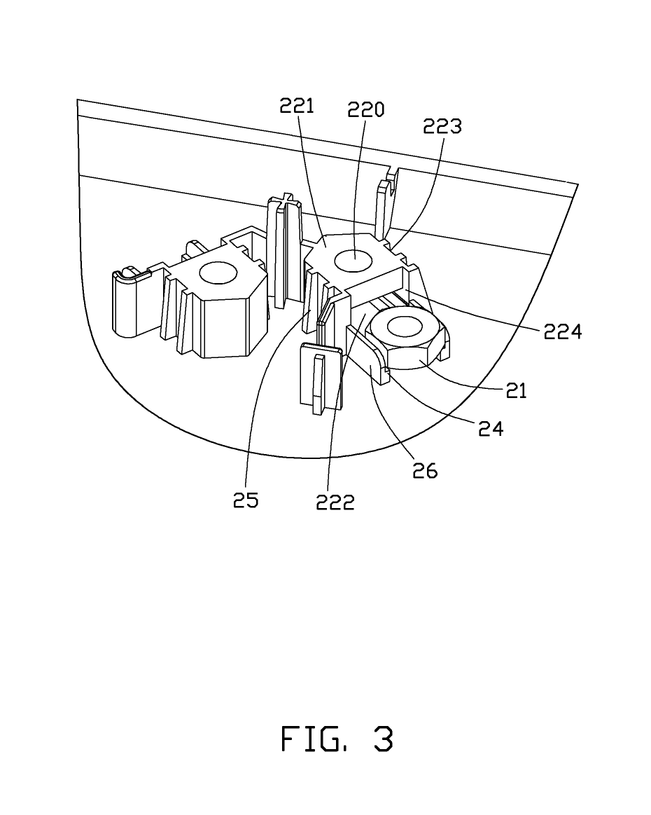

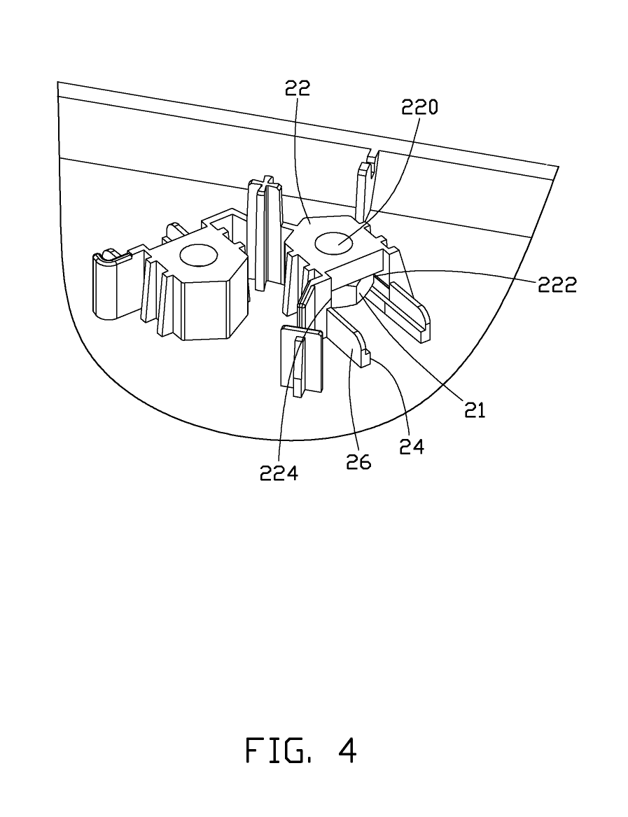

Referring to FIGS. 3 and 4, each fastening structure 20 includes a nut 21, a mounting member 22 positioned on the housing 10 for receiving the nut 21, and a screw 23 cooperating with the nut 22 to fasten the assembly member 30. The nut 21 is a hex nut.

The mounting member 22 protrudes from the housing 10. The mounting member 22 includes a top wall 221 away from the housing 10, a sidewall 223 around the top wall 221 and connected between the housing 10 and the top wall 221, and a receiving groove 222 formed by the top wall 221 and the sidewall 223. The receiving groove 222 is configured to detachably receive the nut 21, such that the nut 21 is prevented from moving in the receiving groove 222. The sidewall 223 defines an opening 224 communicating with the receiving groove 222, such that the nut 21 is capable of being moved into the receiving groove 222. The top wall 221 defines a mounting hole 220, the mounting hole 220 communicates with the receiving groove 222. The mounting hole 222 is concentric with the nut 21.

Each fastening structure 20 further includes two sliding tracks 24, two blocking members 26, and a plurality of supporting members 25. The sliding tracks 24, the blocking members 26, and the supporting members 25 protrude from the housing 10, and connect to the mounting member 22.

The two sliding tracks 24 are two strips, and parallel with each other. The sliding tracks 24 extend from inside of the receiving groove 222 toward outside of the receiving groove 22 via the opening 224. The sliding tracks 24 are connected to two facing sides of the receiving groove 222. The two sliding tracks 24 enable the nut 21 to slide into the receiving groove 222. As a result, the nut 21 can easily be inserted into the receiving groove 222.

The two blocking members 26 are planar boards protruding from the housing 10, and connect to the sliding tracks 24 respectively. Each blocking member 26 is positioned on a side of one sliding track 24 and away from the other sliding track 24. The blocking members 26 extend from the outside end of the sliding tracks 24 to the sidewall 223. The blocking members 26 are capable of resisting against opposite side of the nut 21 when the nut 21 slides along the sliding tracks 24. As a result, the nut 21 is prevented from falling off from the sliding tracks 24.

The supporting members 25 are connected to the outside of the sidewall 223 to support the mounting member 22. As a result, the mounting member 22 is robust.

The assembly member 30 is mounted to the housing 10. First, the assembly member 30 is placed on the top wall 221 of the mounting member 22, and the through hole 31 are concentric with the mounting hole 220. Second, the screw 23 passes one through hole 31 and one mounting hole 220 in that order to engage with the nut 21. At this time, the assembly member 30 is mounted to the housing 10.

As described above, the electronic device 100 and the fastening structure 20 includes the mounting member 22 to secure the nut 21. As a result, the nut 21 is easily secured to housing 10. Further, the nut 21 can be detached from the mounting member 22 to use again.

It is to be understood, however, that even though relevant information and the advantages of the present embodiments have been set forth in the foregoing description, together with details of the functions of the present embodiments, the disclosure is illustrative only; and changes may be made in detail, especially in the matters of shape, size, and arrangement of parts within the principles of the present embodiments to the full extent indicated by the broad general meaning of the terms in which the appended claims are expressed.

What is claimed is:

1. A fastening structure for fastening an assembly member to a housing, the fastening structure comprising:
a mounting member protruding from the housing, the mounting member defining a receiving groove and a mounting hole communicating with receiving groove; and
a nut detachably received in the receiving groove, the nut being capable of engaging with a screw inserted through a through hole defined in the assembly member and the mounting hole to fasten the assembly member to the housing.

2. The fastening structure of claim 1, wherein the mounting member further comprises a top wall away from the housing, and a sidewall protruding from the housing and around the top wall, the sidewall defines an opening, the mounting hole is define in the top wall, the receiving groove is defined by the top wall and the sidewall, the receiving groove communicates with the opening.

3. The fastening structure of claim 1, further comprising two parallel sliding tracks, the sliding track extending from the inside of the receiving groove toward the outside of the mounting member via the opening, the sliding tracks enabling the nut to slide in to the receiving groove.

4. The fastening structure of claim 3, further comprising two blocking member, the blocking members protruding from the housing, and each blocking member positioned on a side of one sliding track away from the other sliding track.

5. The fastening structure of claim 1, wherein the nut is a hex nut.

6. The fastening structure of claim 1, further comprising a plurality of supporting member, the supporting members protruding from the housing and support the mounting member.

7. An electronic device comprising:
a housing;
an assembly member defining a through hole; and
a fastening member to fasten the assembly member to the housing; the fastening member comprising:
a mounting member protruding from the housing; the mounting member defining a receiving groove, and a mounting hole communicating with receiving groove; and
a nut detachably received in the receiving groove, the nut being capable of engaging with a screw inserted through the assembly member and the mounting hole to fasten the assembly member to the housing.

8. The electronic device of claim 7, wherein the mounting member further comprising a top wall away from the housing, and a sidewall protruding from the housing and around the top wall, the sidewall defines an opening, the mounting hole is define in the top wall, the receiving groove is defined by the top wall and the sidewall, the receiving groove communicates with the opening.

9. The electronic device of claim 7, wherein the fastening structure further comprises two parallel sliding tracks, the sliding track extending from the inside of the receiving groove toward the outside of the mounting member via the opening, the sliding tracks enabling the nut to slide in to the receiving groove.

10. The electronic device of claim 9, wherein the fastening structure further comprises two blocking member, the blocking members protrude from the housing, and each blocking member is positioned on a side of one sliding track away from the other sliding track.

11. The electronic device of claim 7, wherein the nut is a hex nut.

12. The electronic device of claim 7, wherein the fastening structure further comprises a plurality of supporting member, the supporting members protrude from the housing, and support the mounting member.
